(19) United States
(12) Patent Application Publication
(10) Pub. No.: US 2013/0316079 A1
(43) Pub. Date: Nov. 28, 2013

(54) Device and Process for Coating a Substrate

(71) Applicants: Jens Ellrich, Wiesbaden (DE); Emmerich Manfed Novak, Kloster Lehnin (DE); Andreas Caspari, Wendel (DE)

(72) Inventors: Jens Ellrich, Wiesbaden (DE); Emmerich Manfed Novak, Kloster Lehnin (DE); Andreas Caspari, Wendel (DE)

(73) Assignee: LEYBOLD OPTICS GMBH, Alzenau (DE)

(21) Appl. No.: 13/880,638

(22) PCT Filed: Oct. 21, 2011
(86) PCT No.: PCT/EP2011/005322

§ 371 Date: Aug. 7, 2013

(30) Foreign Application Priority Data
Oct. 21, 2010 (DE) 10 2010 049 017.2

(51) Int. Cl. C23C 16/04

(52) U.S. Cl. CPC C23C 16/042
USPC 427/248.1; 118/720

(57) ABSTRACT

The invention relates to an apparatus (1) for coating a surface (21) of a substrate (20). The apparatus comprises a processing chamber (2) with a particle source (3) for producing coating particles (19), which are also deposited on the inner wall (5) of the processing chamber (2) and on shielding apparatuses (4′) arranged therein during operation, in addition to the desired coating of the substrate surface. As the operating time increases, the layer thickness of these deposits (6) grows until the latter undergo spalling, which can lead to contamination of the substrate surfaces to be coated. In order to prevent this, shielding screens (10, 10′) are arranged on the inner wall (5) of the processing chamber (2) and/or on the shielding apparatuses (4′) and prevent deposits (6, 7) which undergo spalling from passing into the interior (17) of the processing chamber (2). The shielding screens (10, 10′) consist preferably of an expanded metal.

The invention also relates to a process for coating a surface (21) of a substrate (20), including
receiving the substrate (20) in a processing chamber (2) during the coating process,
producing coating particles (19) using a particle source (3),
allowing coating particles (19) to penetrate into a region between a shielding screen (10, 10′), which is arranged between the particle source (3) and a surface (5, 5′) facing toward the interior (17),
detaining deposits (6), which have spalled from the surfaces (5, 5′), in the region between the shielding screen (10, 10′) and the surface (5, 5′) by means of the shielding screen (10, 10′).

The invention relates to an apparatus and an apparatus for coating a surface of a substrate in each case according to the preambles of the independent claims.

In the optical and the optoelectronic industry, substrate surfaces are typically coated with the aid of chemical and/or physical vapor deposition processes (CVD, PVD), in which the desired coating material is produced in the form of a particle vapor or gas in one or more particle source(s) and deposited on the substrate surface. The coating process generally takes place in a processing chamber in vacuo or in an inert gas atmosphere. During the coating process, coating material is deposited on the substrate surface, where it forms the desired coating. However, some of the coating material passes onto the walls of the coating chamber and onto further shielding devices located in the coating chamber, where it forms undesirable but unavoidable deposits. As the operating time of the coating apparatus increases, the layer thickness of these deposits increases, until the latter undergo spalling or crumble on account of residual stresses. There is then the risk of contamination of the substrate surfaces to be coated, which can lead to defective coatings and/or to fracturing of the substrate material and results in an increased reject rate.

In order to counter this problem, it is known to pretreat the surfaces exposed to the particle vapor in the interior of the coating chamber (chamber walls, shielding apparatuses, etc.) with the aid of special processes (e.g. roughening, plasma coating), in order to ensure a particularly good bond of the deposited coating materials and to prevent spalling. Furthermore, an attempt has been made to position and to form the shielding apparatuses in such a way that the coating particles which possibly undergo spalling are kept away from the substrate surfaces to be coated. Both solutions proved to be inadequate, however.

The invention is therefore based on the object of improving the coating of substrate surfaces in such a way that the risk of substrate contamination during the coating process is reduced.

The object is achieved by the features of the independent claims. Advantageous configurations are the subject of the dependent claims.

According thereto, a preferably extensive shielding screen is provided in the interior of the processing chamber and shields the substrate to be coated from a surface on which deposited coating material collects. The shielding screen is arranged in front of this surface in such a manner that the gaseous or vaporous coating material produced by the particle source (e.g. a sputtering target) can pass through the openings in the shielding screen onto the surface lying behind it, where it can be deposited. The openings in the shielding screen are dimensioned in such a way that deposits which undergo spalling cannot escape through the shielding screen, but rather are detained between the shielding screen and the assigned surface and can be discharged therefrom in a targeted manner. The openings are significantly larger, i.e. have a clear width which is at least twice the size, than the average diameter of the vapor particles, but smaller than the flakes produced by spalling of deposits from the surface.

In this way, spalled deposits are reliably kept away from the substrate to be coated, and therefore instances of contamination of the substrate surface are effectively prevented.

The shieldng screen is preferably arranged in front of selected regions of the inner wall of the processing chamber and/or in front of a shielding plate located in the processing chamber. Further shielding screens can be arranged directly—i.e. avoiding a shielding plate—on the walls of further components, appliances, etc. provided in the processing chamber.

In order to design the protective apparatus to be as compact as possible, the shielding screen expediently runs approximately parallel to and at a small distance from the surface to be shielded. Between the shielding screen and the surface to be shielded, provision is made of a clearance, in which deposits which undergo spalling collect or through which these deposits can be discharged. The height of this clearance is typically between 2 and 10 mm, preferably approximately 5 mm. In order to ensure a stable structure, the shielding screen is advantageously fastened to the assigned surface with the aid of spacers.

In a preferred configuration of the invention, the coating apparatus comprises a collecting chamber, in which the deposits which undergo spalling from the surface are collected so that they can be removed together.

The process according to the invention for coating a surface of a substrate comprises
receiving the substrate in a processing chamber during the coating process,
producing coating particles using a particle source,
allowing coating particles to penetrate into a region between a shielding screen, which is arranged between the particle source and a surface facing toward the interior of the processing chamber,
detaining deposits, which have spalled from the surfaces, in the region between the shielding screen and the surface by means of the shielding screen.

The shielding screen consists preferably—at least in certain portions—of an expanded screen, in particular an expanded metal. It is known that an expanded screen is a workpiece with openings in the surface which are produced by offset cuts with simultaneous expansive deformation of a blank. According to the invention, the openings are dimensioned in such a manner that on the one hand, the gaseous or vaporous particles can pass through the expanded metal onto the wall lying behind it, but that, on the other hand, the deposits which may undergo spalling from the wall can no longer pass back into the coating region. The openings preferably have a clear width of between 0.05 mm and 5 mm, particularly preferably a clear width of between 0.1 mm and 1 mm, whereby it is possible to achieve a particularly reliable detention of spalled material from the substrates to be coated. An expanded screen, in particular expanded metal, can be produced easily and at low cost. The shielding screens consisting of expanded metal can either be formed as consumables or else can be cleaned by sandblasting and reused. Suitable materials for the expanded metal are, for example, alloyed steels or nonferrous metals, which can also be surface-treated and/or coated.

Hereinbelow, the invention will be explained in more detail with reference to an exemplary embodiment shown in the figures, in which:

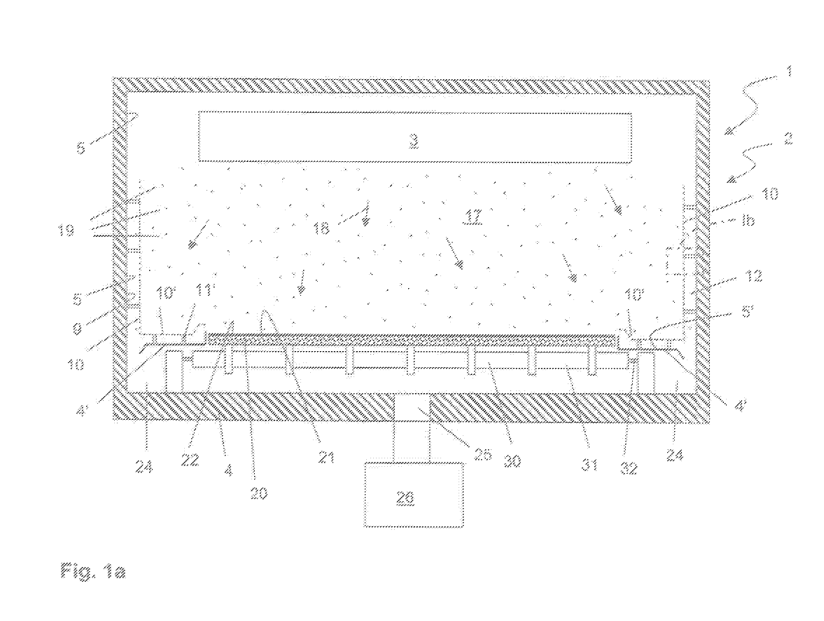

FIG. 1a shows a schematic sectional view through an apparatus for substrate coating, having inner walls and shielding apparatuses which are provided with shielding screens;

FIG. 1b shows a detailed view of a region of an inner wall of the apparatus shown in FIG. 1a, as per the section Ib marked in FIG. 1a;

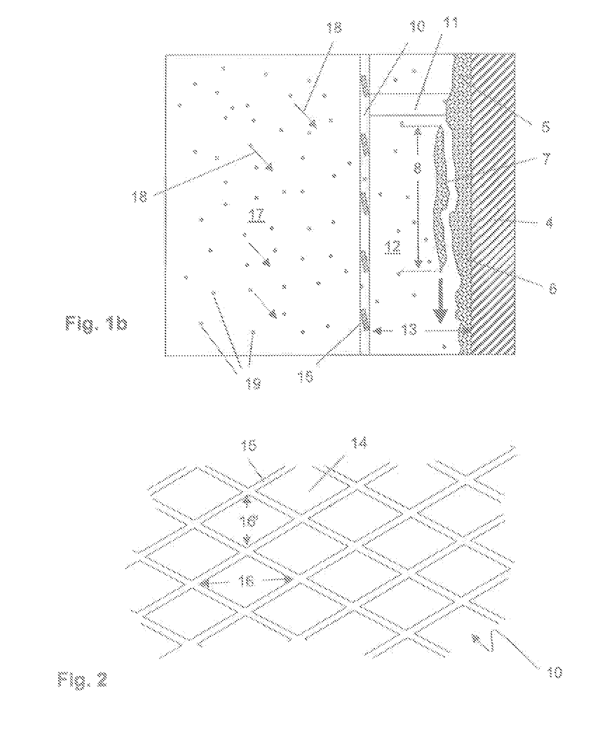

FIG. 2 shows a plan view of a shielding screen formed as expanded metal.

In the drawings, elements which correspond to one another are designated with the same reference signs. The drawings represent a schematic exemplary embodiment and do not reproduce any specific parameters of the invention. Furthermore, the drawings serve merely to explain an advantageous embodiment of the invention, and should not be interpreted in such a way that they restrict the scope of protection of the invention.

FIG. 1a shows a schematic sectional view of an apparatus 1 for coating a surface 21 of a substrate 20 with the aid of a sputtering process. The coating apparatus 1 comprises a processing chamber 2, in the interior 17 of which there are arranged one or more particle sources 3 for producing the vaporous coating particles 19 used for the coating. The vapor particles 19 can be produced, for example, by chemical vapor deposition (CVD), in which a plurality of gaseous starting substances react with one another in order to form the particles 19 in the desired chemical composition. Furthermore, the vapor particles 19 can be produced by physical vapor deposition processes (PVD). In this case, the vapor particles 19 are removed from a target consisting of the coating material with the aid of laser beams, magnetically deflected ions or electrons, by arc discharge etc., move through the processing chamber 2 and are deposited on the substrate 20 and/or on other surfaces 5, 5′ in the interior of the processing chamber 2, where the layer formation occurs. The coating process is effected in vacuo, which is why connections 25 for vacuum pumps 26 are provided in the wall 4 of the processing chamber 2.

The substrate 20 can be for example a large-format glass substrate, which is to be provided in the coating apparatus 1 with a multilayer system 22 for solar applications. The substrate 20 is moved on a feed apparatus 30 through the stream of vaporous coating particles 19 produced by the particle source 3, with the surface 21 of the substrate 20 facing toward the particle source 3 being coated. In the exemplary embodiment shown in FIG. 1a, the feed apparatus 30 is formed by rotatable transporting rollers 31, which are driven with the aid of motors (not shown in the figure) in order to move the substrate 20 through the processing chamber 2.

In addition to the (desired) particle deposition on the substrate surface 21, the vapor particles 19 also settle in particular on the inner walls 5 of the processing chamber 2. With continued operation of the coating apparatus 1, the deposits 6 which have accumulated on these inner walls 5 reach a large layer thickness and spall in the form of flakes 7 (see in this respect the detailed illustration in FIG. 1b). These flakes 7 typically have the form of small flat plates, but can also be present as compact grains or lumps. The size 8 of the flakes 7 is typically between a decimillimeter and several millimeters; the flakes 7 are therefore significantly larger than the vapor particles 19 produced by the particle source 3. In order to prevent the flakes 7 from passing onto the substrate 20 and causing impurities of the substrate 20 and/or of the applied coating 22, selected regions 9 (or the entire area) of the inner wall 5 of the processing chamber 2 are provided with shielding screens 10. The shielding screen 10 runs approximately parallel to the inner wall 5, i.e. follows the contour of the inner wall 5, and is fastened to the wall 4 with the aid of spacers 11, so that a hollow space 12 of the width 13 is formed between the shielding screen 10 and the inner wall 5.

The shielding screen 10 consists of an expanded metal. Expanded metal is an extensive material consisting of a metal sheet or a plastic with openings 14, which are produced by offset cuts and expansive deformation of a starting blank. For use as a shielding screen 10, the expanded metal preferably consists of a thin steel sheet or a sheet made of a nonferrous material. The expanded metal can be surface-treated and/or can be provided with a surface coating.

FIG. 2 shows a plan view of the shielding screen 10 consisting of expanded metal with diamond-shaped openings 14 formed between webs 15. The widths 16 and heights 16′ of the openings 14 are significantly larger than the average diameter of the vapor particles 19, but smaller than the flakes 7 produced by spalling of deposits. Therefore, the vapor particles 19 emitted by the particle source 3 in the direction of the chamber wall 5 (arrows 18 in FIG. 1b) can pass through the shielding screen 10 without major hindrance. The flakes 7 which have split off from the deposits 6 of the inner wall 5 are, however, captured in the hollow space 12 between the wall 5 and the shielding screen 10, and cannot escape into the region of the interior 17 of the processing chamber 2 which is located on that side of the shielding screen 10 (and therefore also do not cause any instances of contamination on the substrate 20). Owing to gravity, the flakes 7 in the hollow space 12 between the wall 5 and the shielding screen 10 fall downward into a collecting chamber 24, from which they can be discharged. The width 13 of the hollow space 12 is typically several millimeters, i.e. the hollow space 12 is wide enough for the flakes 7 which have spalled from the wall surface 5 to be able to pass unhindered downward into the collecting chamber 24.

In order to allow the vapor particles 19 to penetrate into the hollow space 12 between the shielding screen 10 and the wall 4 with as little hindrance as possible, the expanded metal can be formed in such a manner that the webs 15 thereof—as indicated in FIG. 1b—are tilted with respect to the plane of the expanded screen. Furthermore, the expanded metal can be provided with structures (beads etc.) which increase stiffness, in order to increase the inherent stiffness of the shielding screen 10.

The vapor particles 19 are deposited not only on the substrate surface 21 and the chamber walls 5, but on all surfaces 5′ which are exposed to the particle stream unprotected. In order to shield the transporting rollers 31 and the bearing systems 32 thereof from the stream of the coating particles 19, the regions of the transporting rollers 31 which lie laterally alongside the substrate 20 are protected by shielding apparatuses 4′ consisting of a metal sheet, which prevent vapor particles from passing into these regions and impairing the operability of the feed apparatus 30. During coating operation, deposits 6 of coating material also collect on these shielding apparatuses 4′, and can spall and pass onto the substrate 20. In order to prevent such instances of contamination of the substrate 20, the shielding apparatuses 4′ are likewise provided with shielding screens 10′ consisting of expanded metal, which are fastened to the shielding apparatuses 4′ with the aid of spacers 11′.

In addition, further components, appliances, etc. located in the processing chamber 2 can also be provided with shielding screens, which can be fastened directly to the outer wall of these components, appliances, etc. or to the associated shielding apparatuses.

1-12. (canceled)

13. An apparatus for coating a surface of a substrate, the apparatus comprising:
a processing chamber for receiving the substrate during the coating process,
a particle source for producing coating particles,
a shielding screen provided in an interior of the processing chamber, and arranged between the particle source and a surface facing the interior, the shielding screen defining openings which are larger than an average diameter of vapor particles, but smaller than flakes produced by spalling of deposits from the surface, wherein the shielding screen comprises an expanded screen formed with webs which are tilted with respect to a plane of the expanded screen.

14. The apparatus according to claim 13, wherein the shielding screen has an areal structure.

15. The apparatus according to claim 14, wherein the shielding screen is arranged substantially parallel to the surface.

16. The apparatus according to claim 13, wherein the shielding screen is spaced apart from the surface.

17. The apparatus according to claim 16, wherein a distance between the shielding screen and the surface is between 2 and 10 mm.

18. The apparatus according to claim 13, wherein the shielding screen is arranged between the particle source and an inner wall of the processing chamber facing the interior of the processing chamber.

19. The apparatus according to claim 13, wherein the shielding screen is arranged on a surface facing the particle source of an extensive shielding apparatus located in the interior of the processing chamber.

20. The apparatus according to claim 13, wherein the shielding screen is fastened to the surface with one or more spacers.

21. The apparatus according to claim 13, further comprising a collecting chamber for receiving the spalled deposits which have collected between the shielding screen and the surface.

22. A process for coating a surface of a substrate, including:
receiving the substrate in a processing chamber during the coating process,
producing coating particles using a particle source,
allowing coating particles to penetrate into a region between a shielding screen, which is arranged between the particle source and a surface facing an interior of the processing chamber,
detaining deposits, which have spalled from the surface, in a region between the shielding screen and the surface by means of the shielding screen, wherein the shielding screen comprises an expanded screen formed with webs which are tilted with respect to the plane of the expanded screen.
